(19) United States
(12) Patent Application Publication
(10) Pub. No.: US 2003/0094678 A1
(43) Pub. Date: May 22, 2003

(54) Wireless bonded semiconductor device and method for packaging the same

(75) Inventors: Kou-Way Tu, Hualian City (TW); Feng-Tso Chien, Chung-Li City (TW); You-Ren Li, Taichung Hsien (TW); Cheng-Hui Tung, Tucheng City (TW)

Correspondence Address: BUCKNAM AND ARCHER, 1077 Northern Boulevard, Roslyn, NY, 11576-1696, US

(73) Assignee: CHINO-EXCEL TECHNOLOGY CORP., Chung-Ho City (TW)

(21) Appl. No.: 10/298,978

(22) Filed: Nov. 18, 2002

(30) Foreign Application Priority Data
Nov. 19, 2001 (TW) 090128579
Nov. 19, 2001 (TW) 090128580

(51) Int. Cl. H01L 23/495

(52) U.S. Cl. 257/676

(57) ABSTRACT

A wireless bonded semiconductor device comprises a semiconductor chip packaged on a metal lead frame, in which the semiconductor chip contains at least one contact electrically connected to a lead frame and a connecting-pin terminal leading out from its bottom face, and at least one contact and a plurality of individual connecting-pin terminals leading out from its top face, there is no metal bonding wire exists between the surface contact and individual connecting-pin terminals, instead a matrix of the connecting-pin terminal with pre-determined extension length that directly folded and bonded onto the surface contact of the semiconductor chip is employed.

### FIELD OF THE INVENTION

The present invention relates to a wireless bonded semiconductor device and method for packaging the same, especially to a manufacturing process of semiconductor device by rolling a matrix of extended lead frame into individual connecting-pin terminals with predetermined length, which are directly soldered onto surface contacts of the semiconductor chip without any wire bonding.

### BACKGROUND ART

In the conventional manufacturing process of a semiconductor device of high current power transistors such as a TO packaged metal-oxide-semiconductor power transistor (MOSFET), an insulating gate bipolar transistor (IGBT), a bi-carriers junction transistor (BJT), a power diode (DIODE), or a rectifier (RECTIFIER), it is inevitably to form a connection between chip contact and connecting-pin terminal by bonding a metal wire. Since the process of this fine machining may cause high ratio of failure and the metal wire has a small cross-section area and thus a large resistance; the drain/source (or collector/emitter) has a large ON-resistance (i.e., RDS-ON), a small ON-current, and a large corresponding power loss accompany with greater heat that will then influence the life of the product. The manufacturer of high power semiconductor has an urgent course of solving how to reduce ON-resistance, how to increase the ON-current, and how to promote the features of product. Therefore, the inventors thought of providing the matrix of connecting-pin terminal with a predetermined length extension directly soldered onto the gate and source contacts of a semiconductor chip. It is found that this method not only has no wire bonding, but also reduces heat in addition to the reduction of ON-resistance and the increase of ON-current. It is also found that such a method is capable of simplifying the manufacture process, increasing the yield, and reducing the packaging cost.

The patent publication No.404031 of R.O.C., entitled “A system and method of connecting a semiconductor device to a lead frame and a lead frame of bonding support device”, in which the system mainly comprises: a 3 D lead frame including a first lead having a first base portion, a first lead tip, and a first radial axial line; a second lead having a second base portion, a second lead tip, and a second radial axial line; the first and the second lead being formed substantially next to each other, wherein the second lead has a step shaped portion so that tips of the first and the second leads will split in Z-direction and X-direction (the Y-direction is parallel to the radial axial line of the lead, while the X-direction is perpendicular to the adjacent leads); and a bonding support device for supporting above 3 D lead frame, said support device comprises: a support body, formed with a groove, said groove has a first surface with first height to support the second lead tip, and a second surface with second height on said support body, substantially approaching the first surface and the second surface to support the first lead tip, wherein the first height and second height are shifted from each other.

As shown from the claims of above patent, the first lead tip has a protrusion portion which is much protruded that the tip of the second lead. However, the design may adapt to accommodate more lead in the unit area of the chip, and has the first lead and the second lead displaced from each other in both horizontal and vertical directions. Therefore, it is necessary to make connection between the lead and contact of the chip via a bonding wire.

### SUMMARY OF THE INVENTION

The major object of present invention is to provide a wireless bonded semiconductor device comprising a semiconductor chip packaged on a metal lead frame, in which the semiconductor chip contains at least one contact electrically connected to the lead frame and a connecting-pin terminal leading out from its bottom face, and at least one contact and a plurality of individual connecting-pin terminals leading out from its top face, there is no metal bonding wire connection existing between the surface contact and individual connecting-pin terminals, instead a matrix of the connecting-pin terminals with pre-determined extension length which are directly folded and soldered onto the surface contacts of the semiconductor chip is employed.

Another object of the present invention is to provide a method for packaging above mentioned semiconductor chip comprising the following steps: Firstly, forming a lead frame having a single-piece connecting-pin terminal with an extension of predetermined length and a plurality of individual connecting-pin terminals by rolling the metal matrix; secondly, attaching a semiconductor chip to a mounting face of the lead frame, so that the bottom face contact of the chip is electrically connected to the lead frame; thirdly, dipping solder balls to the surface contacts of semiconductor chip by passing through the solder oven; and finally, folding the extension of the connecting-pin terminals onto the surface of semiconductor chip so as to contact the contacts, respectively, and then melting the solder balls and making electrical connection to each of the individual connecting-pin terminals by passing through the bake oven.

### BRIEF DESCRIPTION OF DRAWINGS

The above and other objects, features, and advantages of present invention will become more apparent from the detailed description in conjunction with the following drawings:

FIG. 1 is a schematic view showing a wireless bonded semiconductor device in accordance with the first embodiment of present invention, in which the mold is represented by dot lines.

FIG. 1a is a schematic view showing the packaging step of a semiconductor device in accordance with the first embodiment of present invention.

FIG. 1b is a front view showing the intermediate step of packaging the semiconductor device in accordance with the first embodiment of present invention.

FIG. 1c is a front view showing the semiconductor device after completion of the packaging step in accordance with the first embodiment of present invention.

FIG. 2 is a schematic view showing a wireless bonded semiconductor device in accordance with the second embodiment of present invention, in which the mold is represented by dot lines.

FIG. 2a is a schematic view showing the packaging step of a semiconductor device in accordance with the second embodiment of present invention.

FIG. 2b is a front view showing the intermediate step of packaging the semiconductor device in accordance with the second embodiment of present invention.

FIG. 2c is a front view showing the semiconductor device after completion of the packaging step in accordance with the second embodiment of present invention.

### DETAILED DESCRIPTION OF THE INVENTION

First, description will be given to a semiconductor device involved in the present invention of high current power transistors such as a TO packaged metal-oxide-semiconductor power transistor (MOSFET), an insulating gate bipolar transistor (IGBT), a bi-carriers junction transistor (BJT), a power diode (DIODE), or a rectifier (RECTIFIER), the semiconductor device has a vertical arrangement, which is an arrangement with drain/collector at the bottom and source/emitter and gate at the top of a chip, wherein the power device may also include a diode, a rectifier and a bi-carriers junction transistor. The application of present invention in the wireless bonded semiconductor device and method of packaging the same will be explained by referring to examples shown in the drawing.

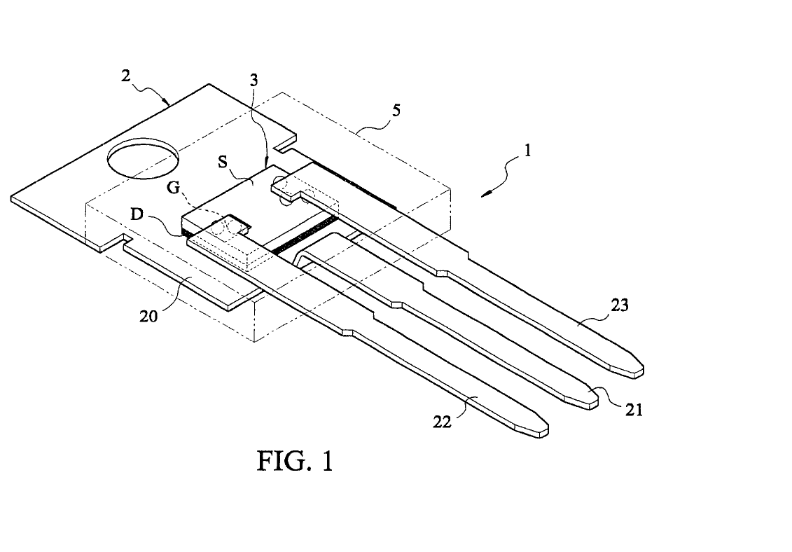

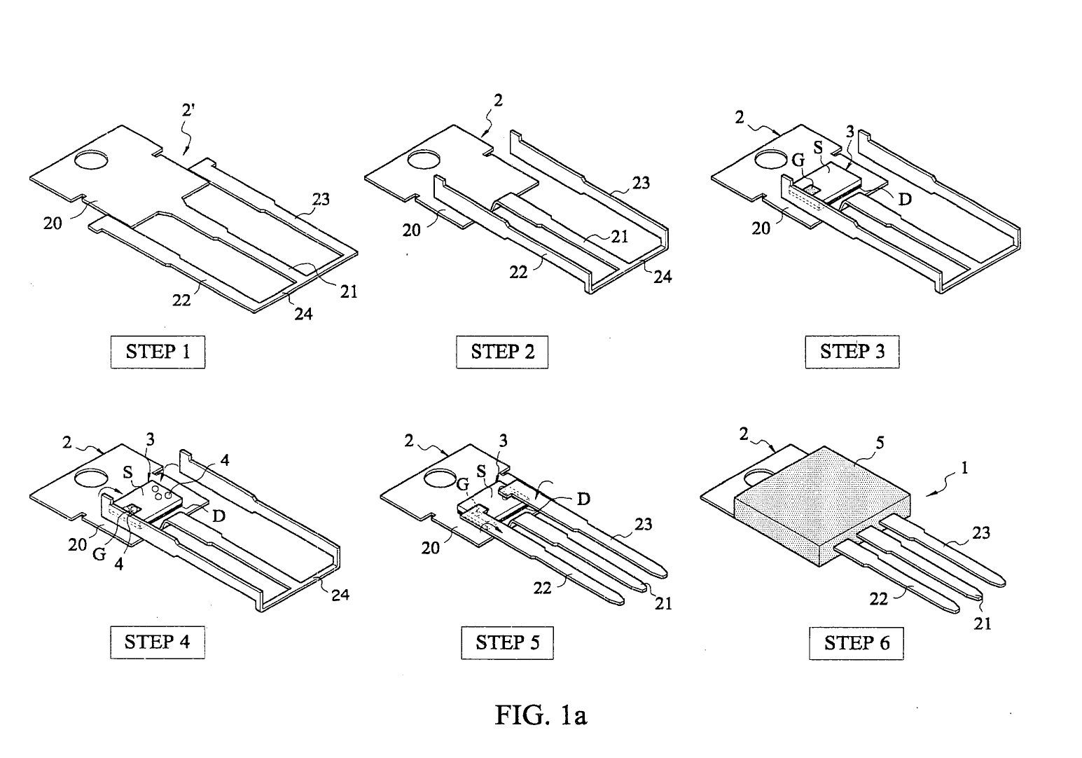

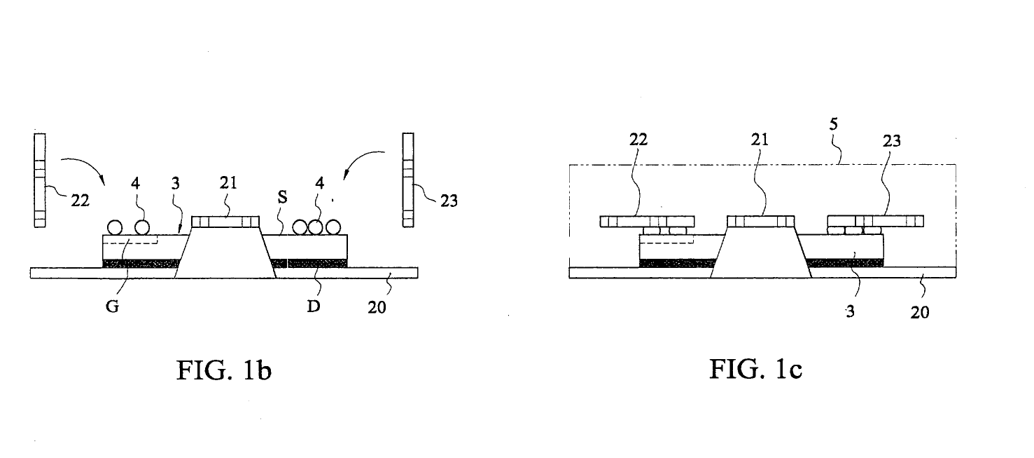

Refer to FIG. 1, a wireless bonded semiconductor device 1 in accordance with the first embodiment of present invention has a basic structure as that of the prior art including a lead frame 2 having one end provided with a expanded mounting face 20 and the other end provided with a connecting-pin terminal 21; a semiconductor chip 3 attached to the mounting face 20 of the lead frame 2, in which the semiconductor chip 3 contains at least one contact (e.g., drain (D)) electrically connected to the lead frame and a connecting-pin terminal of the lead frame leading out from its bottom face, and at least one contact (e.g., gate (G), source (S)) and a plurality of individual connecting-pin terminals 22,23 leading out from its top face.

The semiconductor device 1 of the invention is different from that of the prior art in which the semiconductor chip 3 has no wire connection between the surface contacts (G/S) and individual corresponding connecting-pin terminals 22,23, instead a matrix of the connecting-pin terminal 22,23 with pre-determined extension length that directly folded and bonded onto the surface contacts (G/S) of the semiconductor chip 3 is employed. Thus, there is no metal bonding wire between the surface contact (Gate/Source) and individual corresponding connecting-pin terminals, while increasing the attached area and resulting in a connecting-pin terminal with a increased area so that the ON-resistance can be reduced, the On-current can be increased, and heat can be further reduced.

Then refer to FIG. 1a and compare to FIGS. 1b and 1c, a method of packaging the wireless bonded semiconductor device in accordance with the first embodiment of present invention comprises the following steps:

Step 1: First, by rolling the conductive metal matrix to form a shape 2′ of lead frame, on which one end is formed with an expanded mounting face 20 and the other end is provided with a connecting-pin terminal 21. A plurality of separate individual connecting-pin terminals 22,23 are connected on both sides of the connecting-pin terminal 21 via supporting piece 24, the inner end of the plurality of separate individual connecting-pin terminals 22,23 may protrude inward with a predetermined length.

Step 2: By rolling the above shape 2′ of lead frame into a 3 D lead frame 2 to form a connecting-pin terminal 21 and an expanded mounting face 20 in different planes with a vertical drop therebetween, and to form a plurality of separate individual connecting-pin terminals 22,23 in vertical arrangement with respect to the expanded mounting face 20.

Step 3: Attaching a semiconductor chip 3 to the expanded mounting face 20 of the lead frame 2, so that at least one contact (drain, D) on the bottom face of the semiconductor chip 3 is electrically connected to the lead frame 2.

Step 4: Passing the semiconductor device 1 through a solder oven so as to dip solder balls 4 onto the surface contacts (gate G/ source S) of the semiconductor chip 3.

Step 5: Folding and pressing the plurality of separate individual connecting-pin terminals 22,23 toward the center and contacting on the surface contacts (gate, G/ source, S) of the semiconductor chip 3, passing the semiconductor device 1 through a bake oven for heating and pressuring so that the solder balls 4 are melted to form electrical connections with individual connecting-pin terminals 22,23, and then, an insulating adhesive is sprayed onto the surface, and the supporting piece 24 is cut off.

Step 6: Finally, packaging the semiconductor device 1 with ceramic or plastic molding material 5. Since the above method for packaging the wireless bonded semiconductor device 1 in accordance with the first embodiment of present invention can omit the process of forming a metal soldering wire, it is possible to simplify the manufacturing process and increase the yield so as to further reduce the cost.

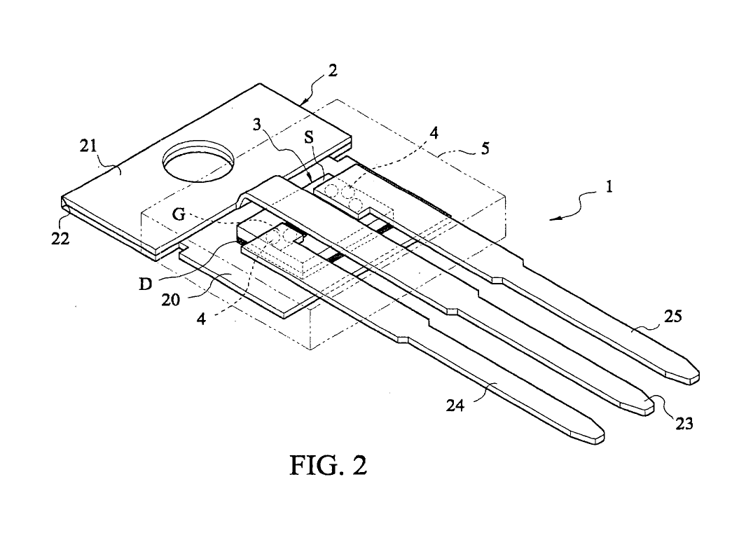

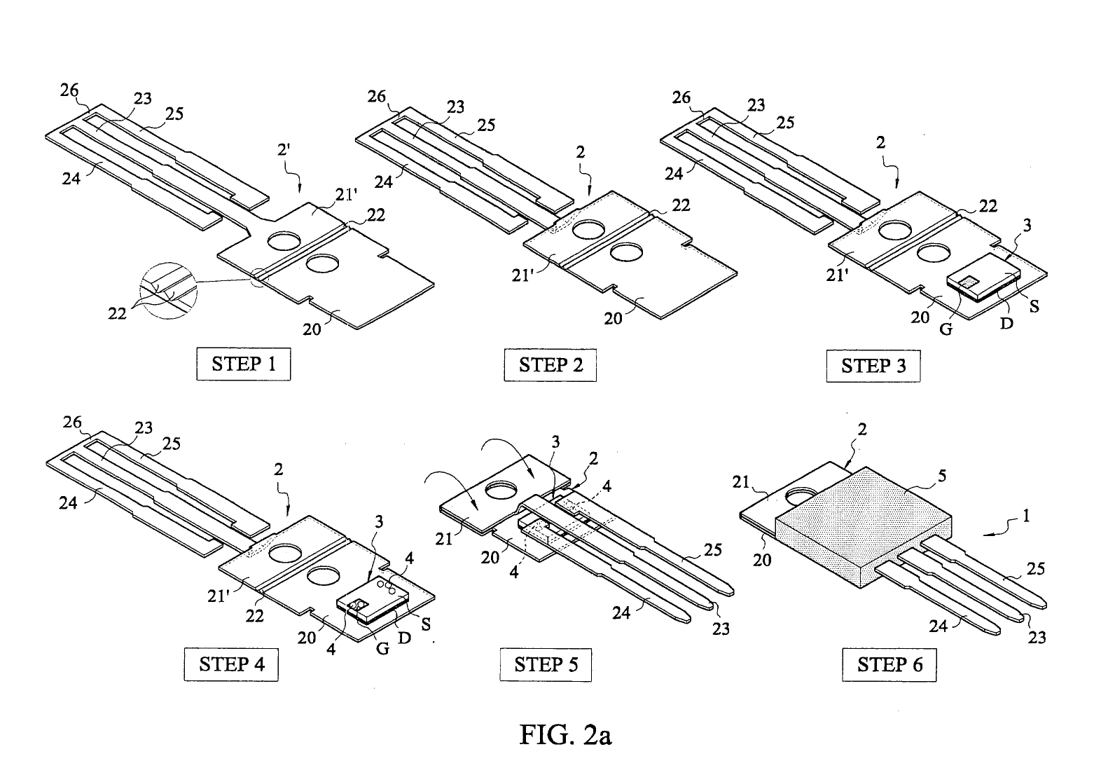

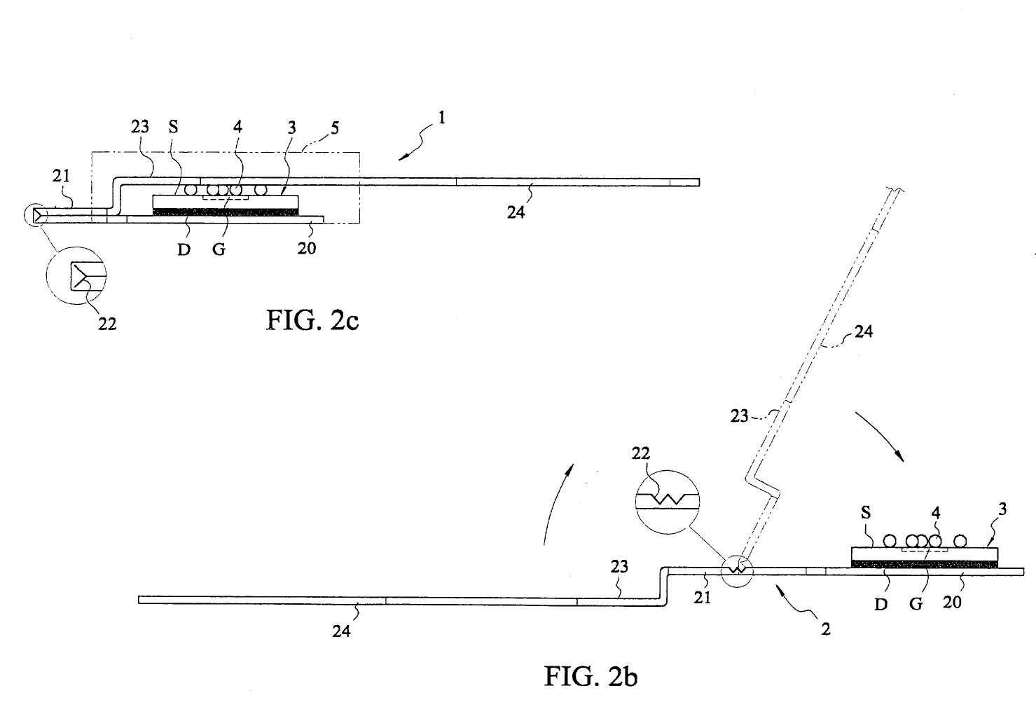

FIG. 2 shows a wireless bonded semiconductor device in accordance with the second embodiment of present invention has a basic structure as that of above embodiment comprising a lead frame 2 having one end provided with a expanded mounting face 20 and a connecting-pin terminal 21 leading out therefrom; a semiconductor chip 3 attached to the mounting face of the lead frame 2, in which the semiconductor chip 3 contains at least one contact (eg., drain) electrically connected to the lead frame 2 on its bottom face, and at least one contact (eg., gate, source) and individual connecting-pin terminals 24,25 leading out from its top face.

The semiconductor device 1 of present embodiment is different from that the above embodiment in which the matrix on the other end of the lead frame 2 may extend outward to form an overlapping layer 21. The overlapping layer 21 has at least one end connected to one end of the mounting face 20 and is rolled to form a groove 22 smaller than the wall thickness inside the connection boundary. The overlapping layer 21 may also extend for a predetermined length and is rolled to form a single piece connecting-pin terminal 23 and individual connecting-pin terminals 24,25. There is no metal bonding wire between the surface contacts (gate, G/ source, S) of the above semiconductor chip 3 and individual corresponding connecting-pin terminals 24,25, instead the individual connecting-pin terminals 24,25 are directly bonded onto the surface contacts (gate, G/ source, S) of the semiconductor chip 3. Thus, it is possible for the method for packaging the semiconductor device 1 in accordance with the first embodiment to have no metal bonding wire between the surface contacts (Gate/Source) and individual correspond connecting-pin terminals, while increasing the attached area and resulting in a connecting-pin terminal with a increased area so that the ON-resistance can be reduced, the ON-current can be increased, and heat emission can be further reduced.

Then, refer to FIG. 2a and compare to FIGS. 2b and 2c, a method for packaging the wireless bonded semiconductor device in accordance with the first embodiment of present invention comprises the following steps:

Step 1: First, by rolling the conductive metal matrix to form a shape 2′ of lead frame, on which one end is formed with an expanded mounting face 20 and the other end is extended to form an exploded face 21′. At least one groove 22 is rolled at the boundary of the expanded mounting face 20 and the exploded face 21′, preferably two triangle grooves 22 is continuously rolled. The outer end of the exploded face 21′ is provided with a connecting-pin terminal 23, a plurality of separate individual connecting-pin terminals 24,25 are connected on both sides of the connecting-pin terminal 23 via supporting piece 26. The inner end of the plurality of separate individual connecting-pin terminals 24,25 may protrude inward with a predetermined length.

Step 2: By rolling the above shape 2′ of lead frame into a 3 D lead frame 2 to form connecting-pin terminals 23,24,25, exploded face 21′ and mounting face 20 in different planes. The height difference is about the thickness of the semiconductor chip 3.

Step 3: Attaching a semiconductor chip 3 to the expanded mounting face 20 of the lead frame 2, so that at least one contact (drain, D) on the bottom face of the semiconductor chip 3 is electrically connected to the lead frame 2, and coating the surface of the semiconductor chip 3 with an insulating adhesive layer.

Step 4: Passing the semiconductor device 1 through a solder oven so as to dip solder balls 4 onto the surface contacts (gate, G/ source, S) of the semiconductor chip 3.

Step 5: Folding and pressing one end of the exploded face 21′ toward one end of the mounting face 20 to form a closely connected overlapping layer 21, and contacting the plurality of separate individual connecting-pin terminals 24,25 onto the surface contacts (gate, G/ source, S) of the semiconductor chip 3, passing the semiconductor device 1 through a bake oven for heating and pressuring so that the solder balls 4 are melted to form electrical connections with individual connecting-pin terminals 24,25, and then insulating adhesive are sprayed onto the surface and the supporting piece 26 is cut off

Step 6: Finally, packaging the semiconductor device 1 with ceramic or plastic molding material 5.

As described above, it is possible for a method for packaging the semiconductor device 1 in accordance with the second embodiment to eliminate the metal bonding wire and to simplify the manufacturing process, to increase the yield, and further to reduce the packaging cost. Examples given above are provided only for preferred embodiments but not to be treated as the limit to the packaging type and application field of the present invention. In the packaging method of both embodiments, a special-purposed chip with inferior heat endurance such as CMOS semiconductor device for image sensor is not suitable to pass the solder oven and operated under high temperature. Therefore, it is possible to perform the packaging process of the semiconductor chip and avoid “step 4” that directly dip solder balls onto the semiconductor device, instead previously dip solder balls to the surface contact of the chip of at a position corresponding to the connecting-pin terminal. For example, previously dipping solder balls to the contact face of the extended end of the connecting-pin terminals 22,23 in the first step of the first embodiment, or previously dipping solder balls to the contact face of the extended end of the connecting-pin terminals 23,24 in the second step of the second embodiment, and then performing a low temperature soldering while passing through the oven, thus it is possible to avoid deteriorating a special chip of higher temperature sensitivity during packaging process. It can be understood that the above method is not only suitable to the three-pins semiconductor device but also to the two-pins semiconductor device such as a power diode, a rectifier and the like; that is to say, all equivalent change and modification without departing from the claim must be considered as fall within the scope of the invention.

To summary, it is possible for the method for packaging the semiconductor device 1 in accordance with the first embodiment to have no metal bonding wire between the surface contact (Gate/Source) and individual connecting-pin terminals, while increasing the attached area and resulting in a connecting-pin terminal with a increased area so that the ON-resistance can be reduced, the ON-current can be increased, and heat can be further reduced, thus the present invention is a novel and industrial applicable invention.

### LIST OF REFERENCE NUMERALS

1 wireless bonded semiconductor device

2 lead frame

2′ shape of lead frame

3 semiconductor chip

4 solder balls

5 ceramic or plastic molding material

20,20′ mounting face

21 connecting-pin terminal

22,23 individual connecting-pin terminals

24,26 support pieces

What is claimed is:

1. A wireless bonded semiconductor device comprises: a lead frame having one end provided with an expanded mounting face and a connecting-pin terminal leading out therefrom; a semiconductor chip mounted on a metal lead frame, in which the semiconductor chip contains at least one contact electrically connected to the lead frame and a connecting-pin terminal leading out from its bottom face, and at least one contact and a plurality of individual connecting-pin terminals leading out from its top face, wherein no metal bonding wire exists between the surface contact and individual connecting-pin terminals, instead a matrix of the connecting-pin terminal with pre-determined extension length that directly folded and bonded onto the surface contact of the semiconductor chip is employed.

2. A wireless bonded semiconductor comprises: a lead frame having one end provided with an expanded mounting face and a connecting-pin terminal leading out therefrom; a semiconductor chip attached to the mounting face of the lead frame, in which the semiconductor chip contains at least one contact electrically connected to the lead frame on its bottom face, and at least one contact and individual connecting-pin terminals leading out from its top face, wherein no metal bonding wire exists between the surface contact and individual connecting-pin terminals, instead a matrix of the connecting-pin terminal with pre-determined extension length that directly folded and bonded onto the surface contact of the semiconductor chip is employed.

3. A method of packaging a wireless bonded semiconductor device comprises the following steps: first, by rolling the conductive metal matrix to form a shape of lead frame, on which one end is formed with an expanded mounting face and the other end is provided with a connecting-pin terminal, a plurality of separate individual connecting-pin terminals are connected on both sides of the connecting-pin terminal via a supporting piece, the inner end of the plurality of separate individual connecting-pin terminals may protrude inward with a predetermined length;
by rolling said shape of lead frame into a 3 D lead frame to form a connecting-pin terminal and an expanded mounting face in different planes, and to form a plurality of separate individual connecting-pin terminals in vertical arrangement with respect to the expanded mounting face;
attaching a semiconductor chip to the expanded mounting face of the lead frame, so that at least one contact on the bottom face of the semiconductor chip is electrically connected to the lead frame;
passing the semiconductor device through a solder oven so as to dip solder balls onto the surface contacts of the semiconductor chip;
folding and pressing the plurality of separate individual connecting-pin terminals toward the center; and
contacting the surface contacts of the semiconductor chip and passing the semiconductor device through a bake oven for heating and pressuring so that the solder balls are melted to form electrical connections with individual connecting-pin terminals and then insulating adhesive is sprayed onto the surface and the supporting piece is cut off; finally, packaging the semiconductor device with a ceramic or plastic molding material.

4. The method according to claim 3, wherein said solder balls is previously dipped to the contact surface of the extended end on the individual connecting-pin terminal of the lead frame.

5. A method for packaging a wireless bonded semiconductor device comprises the following steps:
first, by rolling the conductive metal matrix to form a shape of lead frame, on which one end is formed with an expanded mounting face and the other end is extended to form an exploded face, at least one groove is rolled at the boundary of the expanded mounting face and the exploded face, preferably two triangle grooves is continuously rolled, the outer end of the exploded face is provided with a connecting-pin terminal, a plurality of separate individual connecting-pin terminals are connected on both sides of the connecting-pin terminal via a supporting piece, the inner end of the plurality of separate individual connecting-pin terminals may protrude inward with a predetermined length;
by rolling said shape of lead frame into a 3D lead frame to form connecting-pin terminals, exploded face and mounting face in different planes, the height difference is the thickness of the semiconductor chip;
attaching a semiconductor chip to the expanded mounting face of the lead frame, so that at least one contact on the bottom face of the semiconductor chip is electrically connected to the lead frame, and coating the surface of the semiconductor chip with an insulating adhesive layer;
passing the semiconductor device through a solder oven so as to dip solder balls onto the surface contacts of the semiconductor chip;
folding and pressing one end of the exploded face toward one end of the mounting face to form a closely connected overlapping layer, and contacting the plurality of separate individual connecting-pin terminals onto the surface contacts of the semiconductor chip, passing the semiconductor device through a bake oven for heating and pressuring so that the solder balls are melted to form electrical connections with individual connecting-pin terminals and then insulating adhesive is sprayed onto the surface and the supporting piece is cut off; and
packaging the semiconductor device with ceramic or plastic molding material.

6. The method according to claim 5, wherein each of the overlapping layer and the mounting face of the lead frame has at least one end connected to each other.
